(19) United States
(12) Patent Application Publication
(10) Pub. No.: US 2013/0068949 A1
(43) Pub. Date: Mar. 21, 2013

(54) CHARGED PARTICLE BEAM DEVICE PROVIDED WITH AUTOMATIC ABERRATION CORRECTION METHOD

(71) Applicants: Kotoko Urano, Matsudo (JP); Takeshi Kawasaki, Musashino (JP); Tomonori Nakano, Kodaira (JP); Hiroyuki Ito, Hitachinaka (JP)

(72) Inventors: Kotoko Urano, Matsudo (JP); Takeshi Kawasaki, Musashino (JP); Tomonori Nakano, Kodaira (JP); Hiroyuki Ito, Hitachinaka (JP)

(21) Appl. No.: 13/700,142

(22) PCT Filed: May 27, 2011
(86) PCT No.: PCT/JP2011/062190

§ 371 Date: Nov. 27, 2012

(30) Foreign Application Priority Data
May 31, 2010 (JP) 2010-124315

(51) Int. Cl. H01J 37/26

(52) U.S. Cl. 250/310

(57) ABSTRACT

Disclosed is an aberration measurement method of a charged particle beam device provided with an aberration corrector (4). The method is characterized by: when measuring aberration, (A) the number of pixels or the resolution is changed of a first image and a second image that are benchmarks when measuring field of view offset, and after determining the destination of movement resulting from a rough field of view offset, the number of pixels or the resolution of the first image and the second image are set to the same conditions, and the amount of field of view offset is measured precisely, or (B) a sample having lines in the horizontal direction and in the vertical direction is one-dimensionally scanned, and the amount of movement is measured from the signal position offset. As a result, in a charged particle beam device provided mounted with an aberration corrector, it becomes possible to provide a highly precise aberration measurement method that is not to the detriment of measurement time.

### TECHNICAL FIELD

The invention relates to a charged particle beam device with an aberration corrector mounted therein, and in particular, to a method for adjustment of an aberration corrector in the charged particle beam device.

### BACKGROUND ART

In a device using a focused charged particle beam (probe beam), such as a scanning electron microscope (SEM), an ion-beam machining device (FIB), and so forth, a probe is caused to scan on a sample to thereby execute processing of an observed image or the sample. In the case of these charged particle beam devices, resolution, and working accuracy are dependent on a size of a probe in section (a probe diameter), and the smaller the probe diameter is, the further the resolution, and the working accuracy can be, in principle, enhanced. Now, development of an aberration corrector for the charged particle beam device has been underway in recent years, and progress has so far been made in commercialization thereof. In the aberration corrector, both an electric field and a magnetic field, not rotationally symmetrical with each other, are applied thereto by use of a multipole lens, thereby giving a reverse aberration to the probe beam. Thereby, it is possible to cancel various types of aberrations including a spherical aberration, and a chromatic aberration, occurring to an objective lens, a deflector lens, and so forth.

In the optical system of a conventional charged particle beam device, lenses symmetric to each other, with respect to axial rotation, have been used, so that if the axes of the respective lenses, and the axes of aperture stops are aligned with each other, and the focus as well as a non-point of the objective lens are adjusted, it has, in principle, been possible to adjust the probe diameter to the minimum value. Further, when focus adjustment and non-point correction are executed, adjustment has been carried out by acquiring an image of the probe under a condition that a focus is changed to thereby select a point where a sharpening degree of the image is at the highest, while comparing the sharpening degrees in at least two directions with each other.

On the other hand, in the charged particle beam device provided with the aberration corrector, both the electric field and the magnetic field, not rotationally symmetrical to each other, are applied by the aberration corrector using the multipole lens. Thereby, in these devices, the effect of high-order aberration becomes pronounced although high-order aberration in the conventional optical system that does not exert the effect. To exploit the maximum performance of the device, aberration types (aberration components) contained in the beam, including these aberrations, and respective amounts of the aberration components must be accurately measured, and multipole electric field and magnetic field must be properly adjusted to thereby remove all the aberration components.

As one of the methods of measuring an aberration, there has been known a method whereby an image is picked up in a state where an electron beam tilted against the optical axis of an optical system for use in measurement is caused to fall on the optical system, an sample image movement amount caused by the tilted electron beam is measured, and magnitude (aberration coefficients) of an aberration is calculated on the basis of a change in the movement amount, accompanying a change in tilt-condition, thereby finding the aberration coefficients (refer to, for example, nonpatent literature 1). Upon the tilted electron beam falling on an electron beam passing over the optical axis of an optical system, a destination position of the electron beam undergoes a change according to the magnitude of an aberration, contained in the optical system, whereupon a visual view offset occurs to a sample image. Magnitude as well as a direction of the visual view offset represents a function of the magnitude as well as the type of the aberration, contained in the optical system, a tilt angle, and a tilt condition. Accordingly, if there is carried out a correlation operation between the image before electron beam tilting and the image after the electron beam tilting, at plurality of tilt angles, and tilt directions, respectively, and the magnitude as well as the direction of the visual view offset, due to the electron beam tilting, is measured on the basis of an amount of a pixel offset in each of the two images, thereby finding a formula for a curve (an aberration figure) expressing a locus of image movements, this will enable the aberration coefficients to be found from the factor of the formula.

### CITATION LIST

### Patent Literature

### Nonpatent Literature

Nonpatent literature 1: Ultramicroscopy 38 (1991), pp. 235-240

### SUMMARY OF INVENTION

### Technical Problem

Images subjected to beam tilting from a plurality of directions, respectively, are required for accurate measurement of an aberration. In general, an aberration figure reflects all rotationally symmetrical aberrations contained in an optical system, superimposed on irrotationally symmetrical aberrations contained in the optical system, respectively, so that complex curves are depicted in the aberration figure. Accordingly, to accurately trace the curves, it is necessary to pick up images from a multitude of the tilt directions, respectively, and, in principle, the more the number of the images is, the more accurate is the aberration figure that is obtained, so that measurement accuracy of the aberration coefficients is enhanced. In reality, however, there arises a problem that the more the number of the images is increased, the longer time is required for calculation of amounts of displacements, or acquisition itself of images, in scanning, and retention, respectively.

However, in the case of aberration correction using an aberration corrector, to adjust the corrector, measurement as well as a change in the power supply value of the corrector is often repeated a number of times, which is required because a high-order aberration (parasitic aberration) occurs due to ununiformity of the fields, attributable to safety integrity of a power supply, and working accuracy of the aberration corrector when the power supply value of the aberration corrector is varied, and it is necessary to reduce a spherical aberration of a objective lens, while cancelling these aberrations out each other inside the corrector every time those aberrations occur. For this reason, time necessary for one measurement of an aberration is preferably as short as possible.

Accordingly, to solve those problems, it is an object of the invention to realize execution of an aberration measurement with high precision in a charged particle beam device with an aberration corrector mounted therein, while controlling an operation amount during aberration measurement, thereby enabling time necessary for correction as a whole to be shortened.

### Solution to Problem

To solve the problems described as above, the invention provides a charged particle beam device, and representative ones thereof include the following:

1) a charged particle beam device including an electron beam source for radiating an electron beam, an electron optical system for irradiating a sample with the electron beam, an electron beam detector for detecting an electron beam emitted from the sample irradiated with the electron beam, an aberration corrector for removing an aberration component by application of an electric field, and an magnetic field, not rotationally symmetrical to each other, and a deflector disposed on a side of the aberration corrector, adjacent to the electron beam source, for controlling a route of the electron beam passing through the electron optical system. A beam in an optical condition changed by use of the deflector is used for scanning on a sample having a predetermined pattern, thereby acquiring a plurality of images by use of beams differing in path from each other, and an image formed by cutting out one of the plural images in a scope containing the predetermined pattern, narrower than a region of one other image, is used as a reference image, a means for working out an amount of an aberration on the basis of a differential between the reference image and the one other image being provided.
2) Or a charged particle beam device including an electron optical system for irradiating a sample with an electron beam radiated from an electron beam source, an electron beam detector for detecting an electron beam emitted from the sample irradiated with the electron beam, an aberration corrector for removing an aberration component by application of an electric field, and an magnetic field, not rotationally symmetrical to each other, and a deflector disposed on a side of the aberration corrector, adjacent to the electron beam source, for controlling a route of the electron beam passing through the electron optical system. There are further provided with a means for acquiring two-dimensional brightness distribution information on the basis of a secondary charged particle signal detected by the electron beam detector, a means for acquiring two-dimensional information pieces on a plurality of brightness distributions against the sample by changing an optical condition set by the deflector, and a means for working out an amount of a visual view offset between images of the sample, acquired under optical conditions differing from each other, from the two-dimensional information pieces on the plural brightness distributions.
3) Otherwise, a charged particle beam device including an electron optical system for irradiating a sample with an electron beam radiated from an electron beam source, an electron beam detector for detecting an electron beam emitted from the sample irradiated with the electron beam, an aberration corrector for removing an aberration component by application of an electric field, and an magnetic field, not rotationally symmetrical to each other, and a deflector disposed on a side of the aberration corrector, adjacent to the electron beam source, for controlling a route of the electron beam passing through the electron optical system. There are further provided with a means for acquiring one-dimensional brightness distribution information on the basis of a primary charged particle signal detected by the electron beam detector, a means for acquiring one-dimensional information pieces on a plurality of brightness distributions against the sample by changing an optical condition set by the deflector, and a means for working out an amount of a visual view offset between images of the sample, acquired under optical conditions differing from each other, from the one-dimensional information pieces on the plural brightness distributions.

More specifically, in the present invention, (1) the number of pixels or resolution in the first image serving as the reference as well as in the second image are changed to thereby roughly find a movement destination caused by a visual field offset. Thereafter, the number of pixels or the resolution in the first image is rendered identical in condition to that in the second image to thereby precisely measure a visual field offset amount. Or, (2) the sample having lines extending in the horizontal direction and lines extending in the vertical direction is one-dimensionally scanned to thereby measure image displacement amounts from a signal position offset.

In an image-processing operation, a difference operation is proportional to pixel numbers “n”, but a correlation operation is proportional to the square of “n”. Accordingly, if the first image is cut out small in size onto the second image to thereby grasp an approximate position of a visual view offset by use of the difference operation executed in advance, this will render it possible to reduce a calculation amount of the correlation operation taking much time.

### Advantageous Effects of Invention

According to the present invention, in the charged particle beam device with the aberration corrector mounted therein, execution of an aberration measurement with high precision can be implemented, while controlling an amount of calculation during measuring an aberration, so that time necessary for correction as a whole can be reduced.

### BRIEF DESCRIPTION OF DRAWINGS

FIG. 1 is a system block diagram showing the case where the present invention is applied to an SEM;

FIG. 2 is a flow chart showing aberration correction according to the present, in whole;

FIG. 3A is a view showing a change of a sample image, due to beam-tilting;

FIG. 3B is a view showing a change of another sample image, due to beam-tilting;

FIG. 4A is a view showing a sample image used in a first embodiment of the invention;

FIG. 4B is a view showing another sample image used in the first embodiment of the invention;

FIG. 4C is a view showing still another sample image used in the first embodiment of the invention;

FIG. 4D is a view showing a further sample image used in the first embodiment of the invention;

FIG. 5A is a view showing a still further sample image used in the first embodiment of the invention;

FIG. 5B is a view showing a yet further sample image used in the first embodiment of the invention;

FIG. 6A is a view showing a sample image used in a second embodiment of the invention;

FIG. 6B is a view showing another sample image used in the second embodiment of the invention;

FIG. 7 is a view showing an example of a Laplacian filter;

FIG. 8 is a view showing a method for reduction in a calculation amount during the difference operation;

FIG. 9 is a view showing a sample image used in a third embodiment of the invention;

FIG. 10A is a view showing a change occurring to a sample image, and a beam profile thereof;

FIG. 10B is a view showing a change occurring to the sample image, and the beam profile thereof;

FIG. 11 is a view showing another sample image used in the third embodiment of the invention;

FIG. 12 is a view showing still another sample image used in the third embodiment of the invention;

FIG. 13 is a view showing a further sample image used in the third embodiment of the invention;

FIG. 14 is a system block diagram in the case where the present invention is applied to a measuring SEM; and

FIG. 15 is a view of a GUI, showing an operation screen according to the present invention.

### DESCRIPTION OF EMBODIMENTS

### First Embodiment

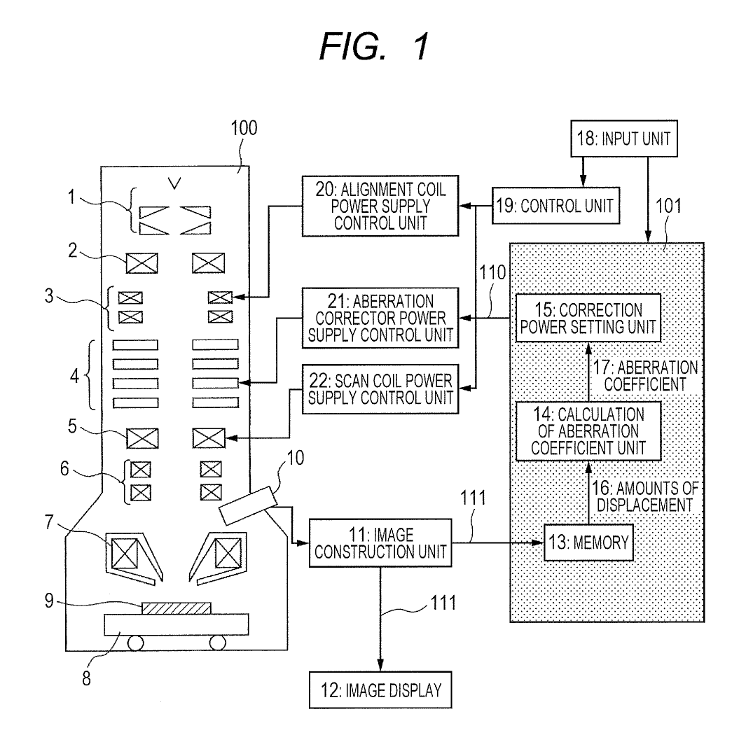

There is described in detail hereinafter an embodiment of a scanning electron microscope (SEM) provided with an aberration corrector of a quadrupole-octopole system electric and magnetic fields superimposition type, as a first embodiment of the invention. In FIG. 1, there is shown a schematic system illustration of the SEM with an aberration corrector 4 mounted therein. The aberration corrector 4 according to the present embodiment is provided with multipole lenses, installed in a plurality of stages, respectively, and is capable of executing high-order aberration correction. In the SEM shown in FIG. 1, an electron beam emitted from an electron gun 1 inside a SEM column 100 passes through a condenser lens 2 and a 2-stage deflection coil 3, and subsequently, falls on the aberration corrector 4. Herein, an electrostatic deflector may be used in place of the 2-stage deflection coil 3. The electron beam (not shown) having passed through the aberration corrector 4 is scaled down by a condenser lens 5 to pass through an objective lens 7, whereupon the electron beam scans a sample 9 on a sample stage 8 by the agency of a scan coil 6. A secondary charged particle (not shown), such as a secondary electron, a reflection electron, and so forth, emitted from the sample 9, is detected as a secondary charged particle signal by a detector 10 to be converted into image data of a brightness distribution scheme via an image construction unit 11 for executing signal amplification, D/A conversion, and so forth, before being outputted to a image display 12. Further, brightness distribution data is accumulated in a memory 13 inside a control PC 101.

Further, the SEM according to the invention has a function for enabling a beam incident on an object point of the objective lens to be tilted against the optical axis of the objective lens. For example, the SEM according to the present embodiment has the 2-stage deflection coil 3 above the aberration corrector 4, and therefore, it is possible to create an electron beam with the center axis thereof, having a tilt angle (τ), and an azimuth θ, against the objective lens. Data on both beam tilting and the azimuth thereof is stored in the memory inside the PC to be referred to during acquisition of an aberration correction, and so forth.

Now, there is broadly described a method for finding an aberration coefficients 17 from amounts of displacement 16 of an image. If an object point is irradiated with a beam in a state having a given tilt angle, an optical path difference occurs to the electron beam due to the tilting of the beam, whereupon an aberration caused by the tilting of the beam is applied to a sample image. In general, if a function expressing an optical path difference due to an aberration is defined as χ(ω), χ(ω) can be analytically expressed by use of plural-order aberrations. Herein, χ(ω) for aberrations up to a three-order aberration can be represented by formula (1) as follows:

$$\begin{matrix} formula ( 1 ) & \\ χ ( ω ) = Re \{ \begin{matrix}\overline{ω} {A}_{0} + \frac{1}{2} ω \overline{ω} {C}_{1} + \frac{1}{2} {\overline{ω}}^{2} {A}_{1} + {ω}^{2} \overline{ω} {B}_{2} + \frac{1}{3} {\overline{ω}}^{3} {A}_{2} + \frac{1}{4} {ω}^{2} {\overline{ω}}^{2} {C}_{3} + \\ {ω}^{3} \overline{ω} {S}_{3} + \frac{1}{4} {\overline{ω}}^{4} {A}_{3} + …\end{matrix} \} & ( 1 )\end{matrix}$$

In expression (1), A₀, C₁, A₁, B₂, A₂, C₃, S₃, and A₃ express an image movement, a defocus, two-fold symmetry astigmatism, an axial coma aberration, three-fold symmetry astigmatism, a tertiary spherical aberration, a star aberration, and four-fold symmetrical astigmatism, respectively. Further, ω expresses complex coordinates on an object surface. Herein, when an incident electron beam is tilted at the tilt angle (τ), χ(ω) can be represented by the following formula (2): it is assumed that the tilt angle (τ) is expressed by a complex number.

$$\begin{matrix} formula ( 2 ) & \\ χ ( ω + τ ) = Re \{ \begin{matrix}\overline{ω} {A}_{0} ( τ ) + \frac{1}{2} ω \overline{ω} {C}_{1} ( τ ) + \frac{1}{2} {\overline{ω}}^{2} {A}_{1} ( τ ) + {ω}^{2} \overline{ω} {B}_{2} ( τ ) + \\ \frac{1}{3} {\overline{ω}}^{3} {A}_{2} ( τ ) + \frac{1}{4} {ω}^{2} {\overline{ω}}^{2} {C}_{3} ( τ ) + {ω}^{3} \overline{ω} {S}_{3} ( τ ) + \frac{1}{4} {\overline{ω}}^{4} {A}_{3} ( τ ) + …\end{matrix} \} & ( 2 )\end{matrix}$$

In expression (2), A₀(τ), and C₁(τ) each express the aberration coefficients 17 when the electron beam is tilted by the tilt angle (τ). The respective aberration coefficients at the time when the electron beam is tilted are expressed as the sum of the aberration coefficients when the beam is tilted at the tilt angle (τ), and an aberration coefficients when the electron beam is not tilted. In the case of taking the aberrations up to the three-order aberration into consideration, an image movement emerging due to tilting is represented as follows:

formula 3

A₀(τ)=A₀+A₁ τ̅+C₁τ+A₂ τ̅²+B₂τ²+2 B̅₂τ τ̅+A₃ τ̅³+C₃τ² τ̅+S₃τ³+3 S̅₃τ τ̅² (3)

As is evident from expression (3), all the aberration coefficients up to the third-order aberration coefficients before tilting are included in A₀(τ). That is, if the function form of A₀(τ), and values of A₀(τ) under several tilt-conditions are known, the aberration coefficients can be found by function fitting.

Next, if an irradiation direction of the electron beam that is tilted is represented in complex-number expression, the tilt angle (τ) can be represented by formula (4) on the basis of a tilt angle (t) against the optical axis of a lens, and an azimuth φ of an electron beam incident on a lens plane.

formula (4):

τ=te^{iφ} (4)

If the expression (3) is replaced with expression (4) to be reorganized, the expression (3) can be finally written in the following form.

$$\begin{matrix}formula ( 5 ) & \\ {\sum }_{k = 0}^{n} {m}_{k} ( t ) {e}^{i k φ} & ( 5 )\end{matrix}$$

Herein, mₖ(t) is a factor expressed by a formula based on linear connection between the respective aberration coefficients before the beam-tilting and “t”. Accordingly, mₖ(t) can be found by measuring several azimuths φ of A₀(τ) at the angle (t) to thereby execute the function fitting, and if equations as obtained are simultaneously solved, this will enable all the aberration coefficients 17 before the beam-tilting to be calculated.

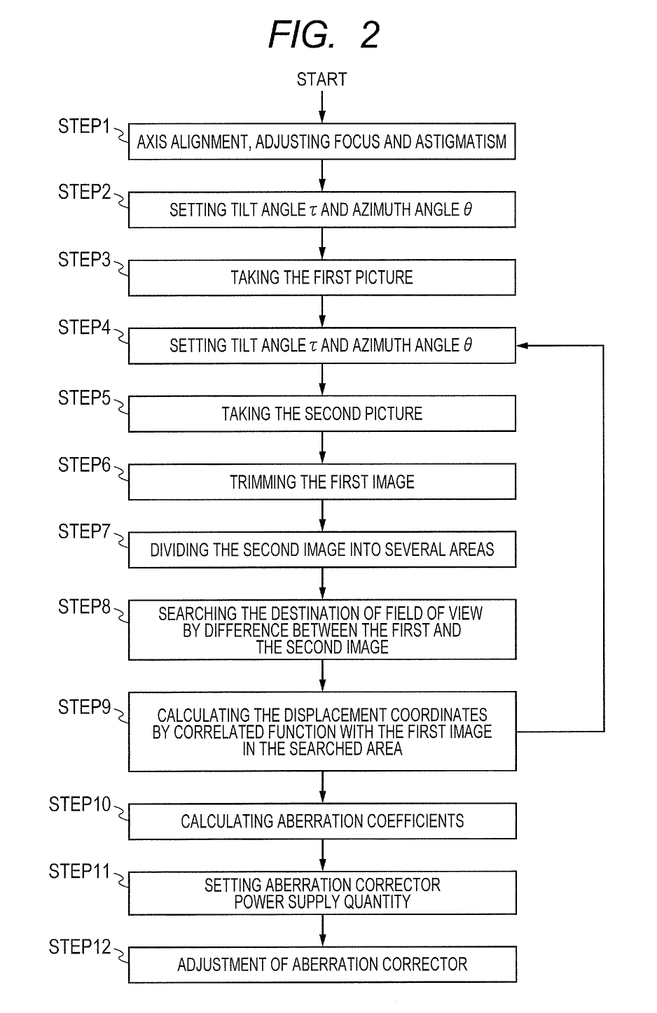

A procedure for use in execution of aberration correction according to the present embodiment is described hereinafter with reference to a flow chart shown in FIG. 2. First, axial alignment, and focus•non-point adjustment are executed (STEP 1) to enable an image to be obtained in a normal beam state where abeam is not tilted, and the initial adjustment of a tilt angle (τ), and an azimuth θ is executed (STEP 2) to thereby record a first image (STEP 3). The first image is an image serving as a reference during measurement of a visual field offset, and the measurement of the visual field offset according to the invention is to measure an extent to which the visual field offset has occurred. After acquisition of the first image, a deflection coil power-supply control unit 20 is activated (STEP4) to thereby acquire a second image (STEP5) with the beam in a state where the tilt angle thereof is changed. Herein, the first image may be obtained in a normal beam state where the beam is not subjected to tilting, or in a beam state where the beam is subjected to tilting. In that case, the second image is picked up in a beam state where the tilting angle is changed against the beam state for acquiring the first image.

Further, control of the deflection coil power-supply control unit 20, and input of information necessary for the control are executed by use of a control unit 19, and an input unit 18, respectively.

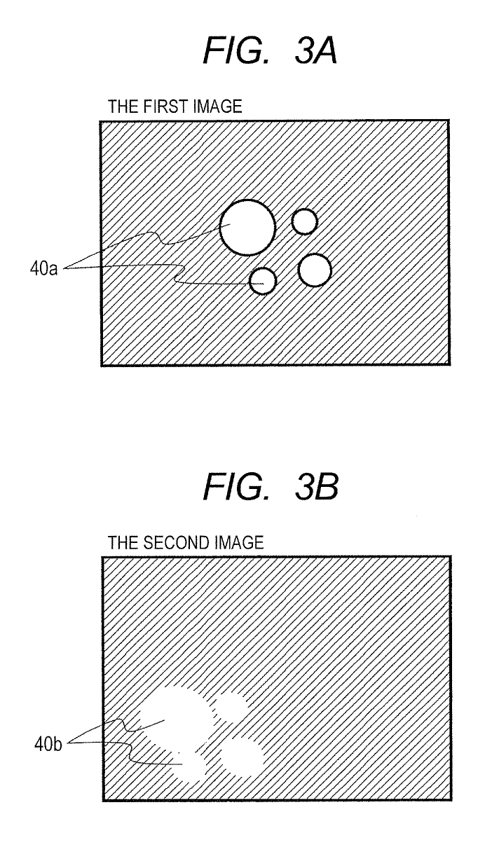

In FIG. 3A, there is shown a schematic diagram of a pattern of a first image, and in FIG. 3B, there is shown a schematic diagram of a second image against the first image. Visual view offset, defocusing, and non-point defocusing occur to the second image according to magnitude of an aberration of an electron optical system. For example, in FIG. 3B, it is evident that patterns 40a shown in FIG. 3A move toward a lower left-side, that is, a visual view offset occurs, and a circle of each of the patterns 40a is transformed into an ellipse, while the outline of a pattern 40b is defocused.

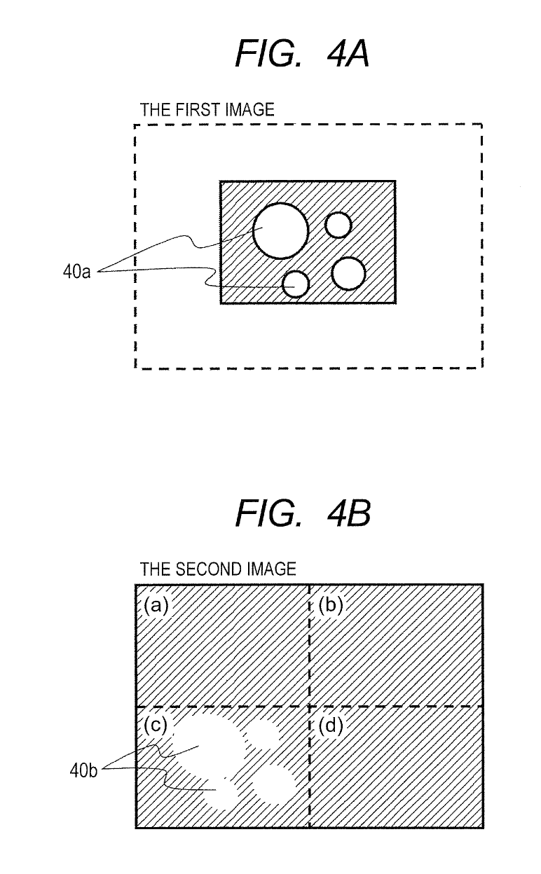

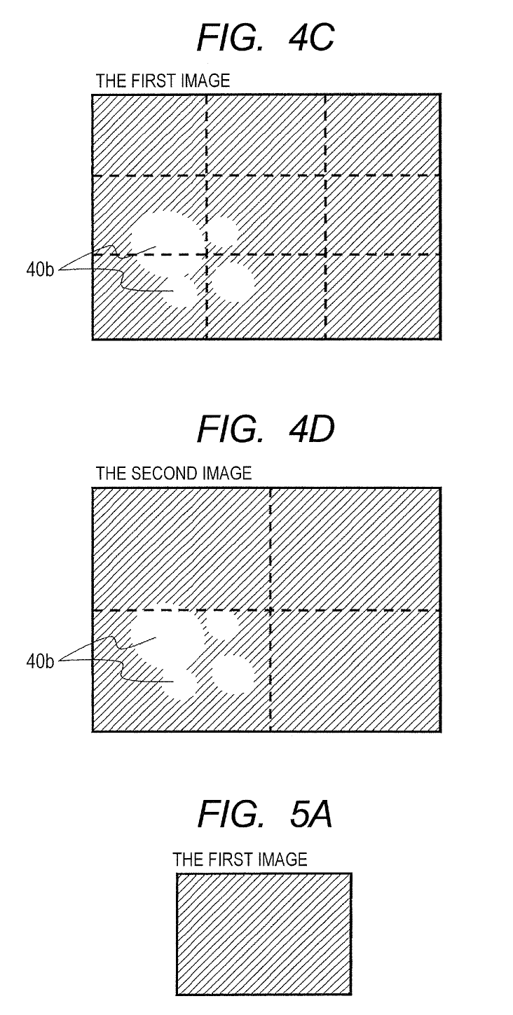

Next, an amount of a visual view offset in the second image is to be found against the first image, and at this point in time, a pixel in the vicinity of the center of the first image is cut out (STEP6), as shown in FIG. 4A, thereby rendering a first image region in the second image shown in FIG. 4B to be relatively small in size. Cutout regions are prepared to amount in number to M/m×N/n against pixel numbers M×N {pix} (m, n: integer) of the initial image, FIG. 4 (B) representing an example where m=n=2. Next, the second image is divided by m, n in an x-direction and a y-direction, respectively, thereby dividing the image as a whole into m×n of small regions (STEP7).

A size of the cutout region is preset by a user before a measurement such that divisors are m, n, in the x-direction, and the y-direction, respectively, against the pixel numbers M×N {pix} of a scanning region in whole. FIG. 4 (B) shows the example where m=n=2. The respective values of the divisors m, n are adequately selected by the user from a proportion of an observation subject to a visual field. If the respective values of the divisors m, n are too large, this will raise a possibility that the cutout region becomes too small, and an amount of information contained in the region is insufficient, thereby rendering it impossible to correctly execute a measurement. Conversely, however, if the respective values of the divisors m, n are too small, this will cause the cutout region to be large in size, thereby reducing effects of reduction in amount of calculation. The respective ranges of m, n are set to a range of 2 to 8 from a practical point of view, and a display magnification is adjusted so as to enable an observation range to fit into this range.

Subsequently, a differential between cells, in the first image, and the second image, respectively, is obtained, and search for a region having a higher differential value is carried out to thereby find a candidate cell at a movement destination. Thereafter, a correlation calculation against the candidate cell is executed to thereby find an amount of movement of the visual view offset, in detail (STEP8).

For example, in the respective cases of FIGS. 4A, 4B, if calculation of a differential from the first image shown in FIG. 4A is executed against four small regions (a), (b), (c), (d) of the second image shown in FIG. 4B, respectively, a differential value in the region (c) is found to be the smallest. Thereafter, a correlation operation between the first image and the region (c) of the second image is executed (STEP9). If the amount of movement, resulting from the operation is defined as (mx, my), and coordinates of the center of gravity of the region (c) are defined as (xc, yc), (mx+cx, my+cy) represent the amount of movement, to be searched for. Such an image calculation as described is executed by an image processing unit inside the PC, and the amount of movement, obtained as a result of the calculation, is stored in the memory 13.

Upon obtainment of the amount of movement, described as above, an tilting angle (τ), and an azimuth θ are newly set (STEP4) to pick up an image of which an amount of a visual view offset is to be measured, thereby repeating this procedure until a target number of data blocks are obtained.

Further, in the case of a visual view offset region in the second image crosses a plurality of regions as shown in FIG. 4C, there is a possibility that an attempt to narrow movement destinations down to a destination candidate by use of difference operation will turn out unsuccessful. FIG. 4C shows an example of (m=n=3). In such a case described as above, if the number of the divisors is decreased as shown in FIG. 4D to thereby carry out searching again, it is possible to accurately identify a position of the sample to be referred to. FIG. 4D shows an example where the number of the divisors is decreased by one.

Thus, if the first image is cut out small in size onto the second image to thereby grasp an approximate position of a visual view offset by use of the difference operation executed in advance, this will render it possible to reduce a calculation amount of the correlation operation taking much time. Since the correlation operation is a calculation to roughly search for the visual view offset, there is no need for accurately grasping the amount of the visual view offset on a pixel-by-pixel basis.

With an image-processing operation, the difference operation is proportional to pixel numbers “n”, and the correlation operation is proportional to the square of “n”, so that if a movement-destination candidate region is searched for according to the differential in advance, and the correlation operation is applied only to a limited number of the candidate regions, this will enable an amount of an operation necessary for calculation of a visual field offset amount to be reduced. Further, if only an image in the central cutout portion is used in peripheral regions of the first image, this will enable the number of data blocks, acting as noise, respectively, to be reduced, so that the amount of movement can be measured with high precision.

To accurately carry out the above described embodiment, it is preferable that a sample used for photographing may have many edges in all the directions in order to increases the information amount of an image. Furthermore, using of an isolated pattern where a sample pattern is present only in part of a visual field region can reduce the number of data blocks acting as noise during the difference calculation, and can thus enhance the precision for identifying the movement destination.

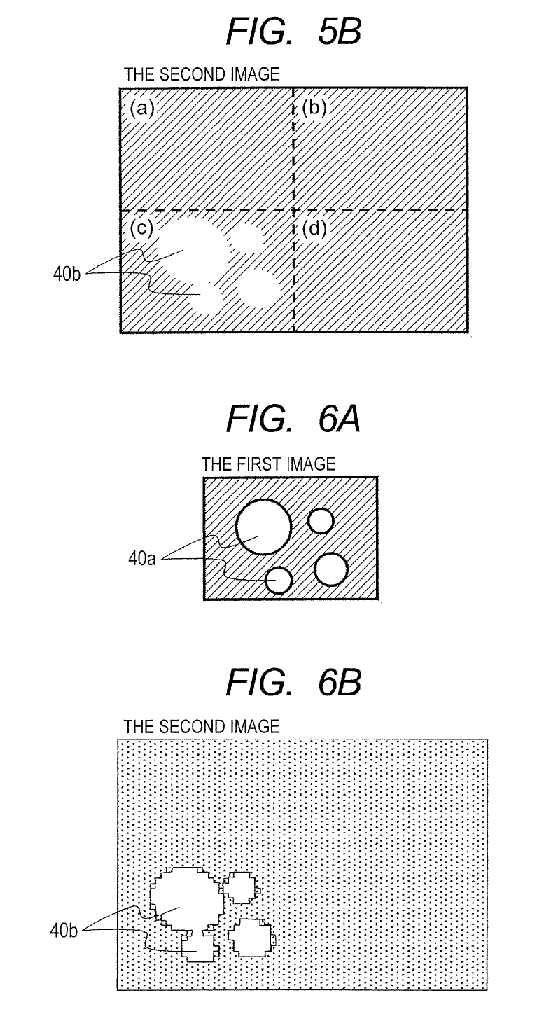

Further, in the case of carrying out a measurement using the isolated pattern, even a region without a pattern present may be used as the first image, as shown in FIG. 5A. In this case, a differential value drops only in the region (c) where a pattern 40b shown in FIG. 5B is present, so that the movement position of the pattern 40b can be identified. Further, in this case, instead of an image picked up every time the first image is photographed, a blank image without any pattern present thereon may be kept stored in the memory 13 inside the PC, and the blank image may be referred to every time the first image is required.

Upon acquisition of data on a desired amount of movement, calculation of the aberration coefficients 17 is executed by aberration coefficients calculation unit 14 on the basis of the data (STEP10) and the result is sent out to a correction power setting unit 15. A table listing the aberration coefficients 17, and respective aberration corrector power supply values corresponding thereto is pre-stored in the aberration correction power setting unit, and a power supply value to be given to the aberration corrector 4 to correct an aberration to a presently desired aberration can be obtained by referring to the table (STEP11). At this point in time, a power supply value to be actually given to the aberration corrector 4 is determined on the basis of the result of an aberration coefficients 17 obtained by the aberration coefficients calculation unit 14, and power supply data to be given to the aberration corrector 4 is sent out to a corrector power-supply controller 21. The power supply value of the aberration corrector 4 is changed via the (aberration) corrector power-supply controller 21, whereupon the aberration correction is executed (STEP12).

### Second Embodiment

FIG. 6 shows another embodiment of the invention, that is, an embodiment whereby an image is obtained by switching resolution between the first image and the second image. In this embodiment, a horizontal scanning frequency of the scan coil 5 is changed via a scan coil power-supply control unit 22 to lower the resolution of the first image, during acquiring the second image, thereby acquiring an image. Further, control of the scan coil power-supply control unit 22, and inputting of information necessary for the control are executed by use of the control unit 19, and the input unit 18, respectively.

The second image as obtained is similarly divided by m, n in the x-direction, and the y-direction, respectively, dividing the image as a whole into m×n of small regions, as is the case with the first embodiment, thereby roughly identifying a movement position by obtaining the differential of the first image on a region-by-region basis. Thereafter, the horizontal scanning frequency of the scan coil is set again to a value identical to, or higher than that during acquiring the first image, and only the vicinity of the destination candidate obtained as a result of differentiation is scanned in high resolution. By execution of the correlation operation as to an image obtained as above, and the first image, movement coordinates in detail can be found.

Since images of visual views in a wide scope can be obtained within the same scanning time by lowering the resolution of the second image, during differential calculation, against the first image, as described above, it is unnecessary to cut out the first image in the case of the present embodiment. Searching in the wide scope is executed in the difference operation, and the correlation operation is executed only in the vicinity of the destination candidate, so that it is possible to reduce an amount of calculation in the correlation operation that takes much time. Furthermore, by scanning only the vicinity of the destination candidate at a high resolution, the correlation operation can be enhanced in precision.

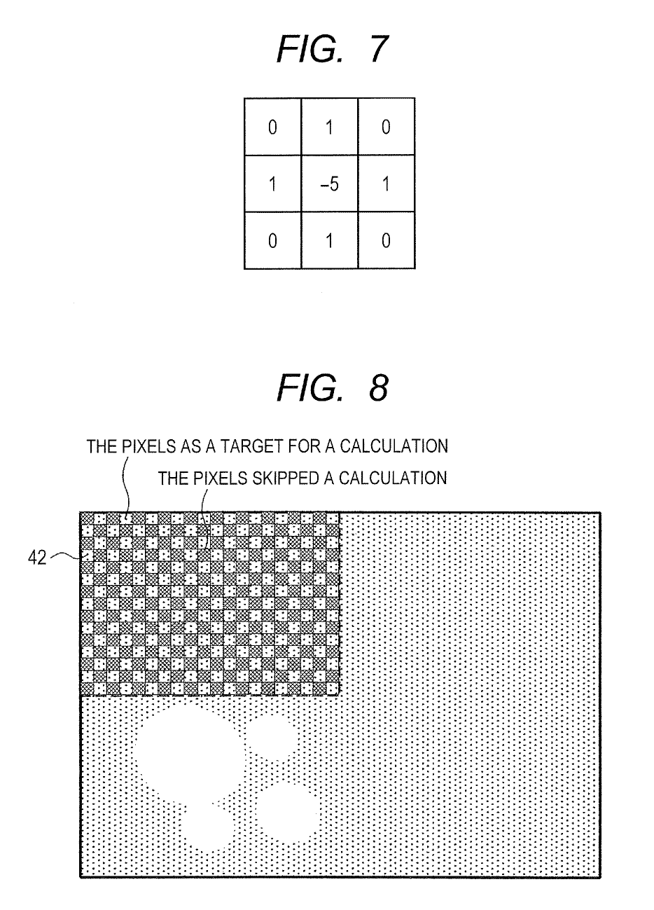

In both the first embodiment and the second embodiment, if a pretreatment using a sharpening filter is applied to the second image, this will reduce effects of defocusing due to tilting to thereby improve the precision of differential searching. FIG. 7 shows an example of the sharpening filter. In FIG. 7, there is shown a 4-vicinity Laplacian filter as one of the sharpening filters. The Laplacian filter is a filter for calculating spatial quadratic differentiation to thereby detect an outline.

Reduction in the amount of the difference operation can also be achieved when the difference operation is executed by executing calculation every n pieces of pixels instead of taking the differential in all the pixels, as shown in FIG. 8. FIG. 8 shows an example where n=2, and every small cell represents a pixel. If calculation in the pixel of a diagonally shaded cell in the figure is omitted during execution of the difference operation, the amount of the difference operation in a region can be held down to one half.

### Third Embodiment

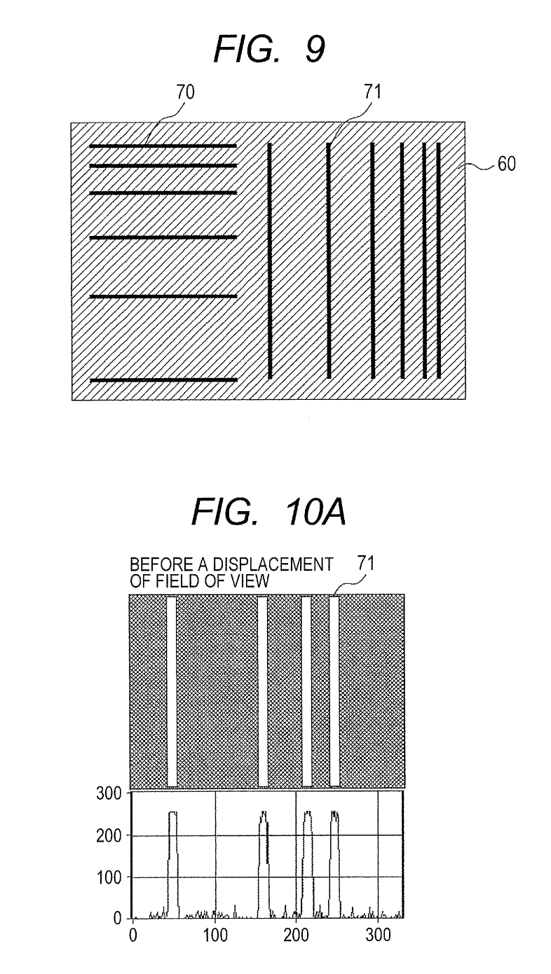

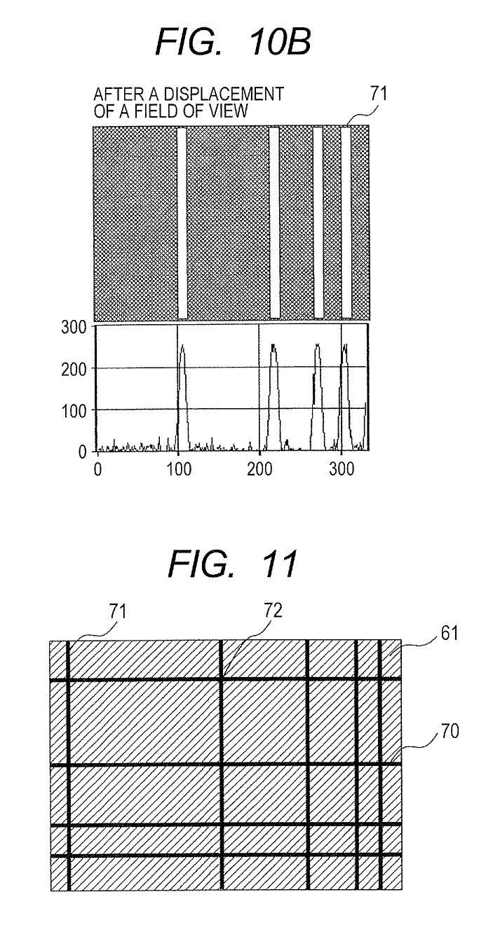

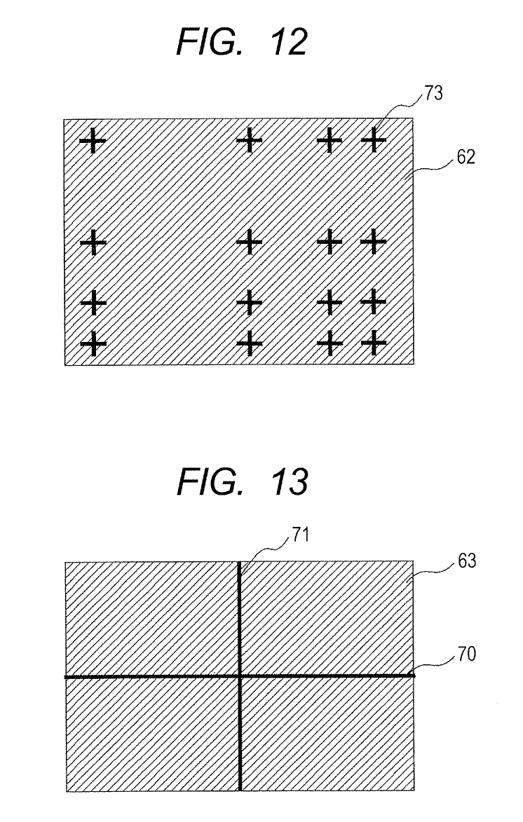

There is shown another example as still another embodiment of the invention, where an amount of movement is measured by use of a sample 60 having lines 70 arranged at unequal intervals in the horizontal direction of a visual field, and lines 71 arranged at unequal intervals in the vertical direction of the visual field, as shown in FIG. 9. Upon observation of the sample 60 using a tilted beam, respective positions of the lines are found shifted due to a visual view offset of an image, caused by an aberration. FIGS. 10A, 10B each show a change occurring to a sample image, and a line profile thereof, by way of example, in the case where the lines in the vertical direction of the visual field are shifted due to the visual view offset. FIG. 10A show a line pattern prior to the visual view offset (an upper stage in the figure), and a pulse waveform's peak position (a lower stage in the figure), while FIG. 10B show a line pattern after the visual view offset, and a pulse waveform's peak position. Thus, the visual view offset of the sample of the line pattern can be measured from movement of the peak position of the pulse waveform of a one-dimensional profile. Further, since the lines are arranged at unequal intervals, a corresponding relationship between the lines before, and after the visual view offset is well defined even in the case where there occurs the visual view offset greater in value than a pitch between the lines.

Accordingly, if the sample as described is scanned one line by one horizontal line, and in the vertical direction, respectively, to thereby examine the line profile, the amount of movement can be measured without acquisition of two-dimensional brightness distribution data, and scanning time can be significantly shortened.

In the present embodiment, it need only be sufficient to have a sample provided with lines arranged at unequal intervals in the horizontal direction, and in the vertical direction, respectively. Accordingly, use may be made of a sample 61 having an unequally-spaced grid pattern 72 shown, for example, in FIG. 11, and a sample 62 with unequally-spaced cross patterns 73 inscribed therein, as shown in FIG. 12.

Otherwise, as shown in FIG. 13, the amount of movement may be measured from movement of the peak position of the pulse waveform of the one-dimensional profile obtained by similarly scanning the lines extending in the x-direction and in the y-direction using a cross pattern where a horizontal line 70 and a vertical line 71 intersect at one place near the center of a visual field to be observed. With this method, pattern designing is easily implemented, and an advantageous effect can be expected if the method is adopted when an amount of aberration correction is estimated small.

### Fourth Embodiment

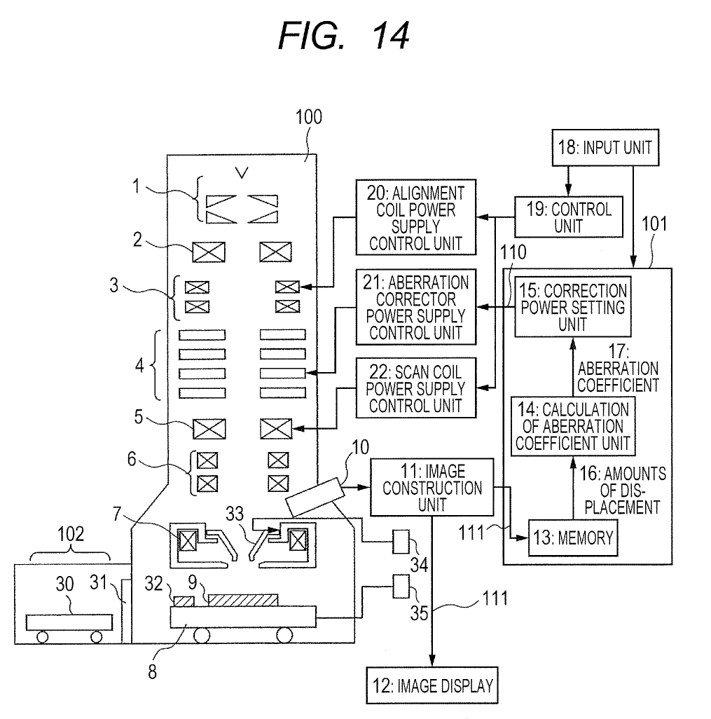

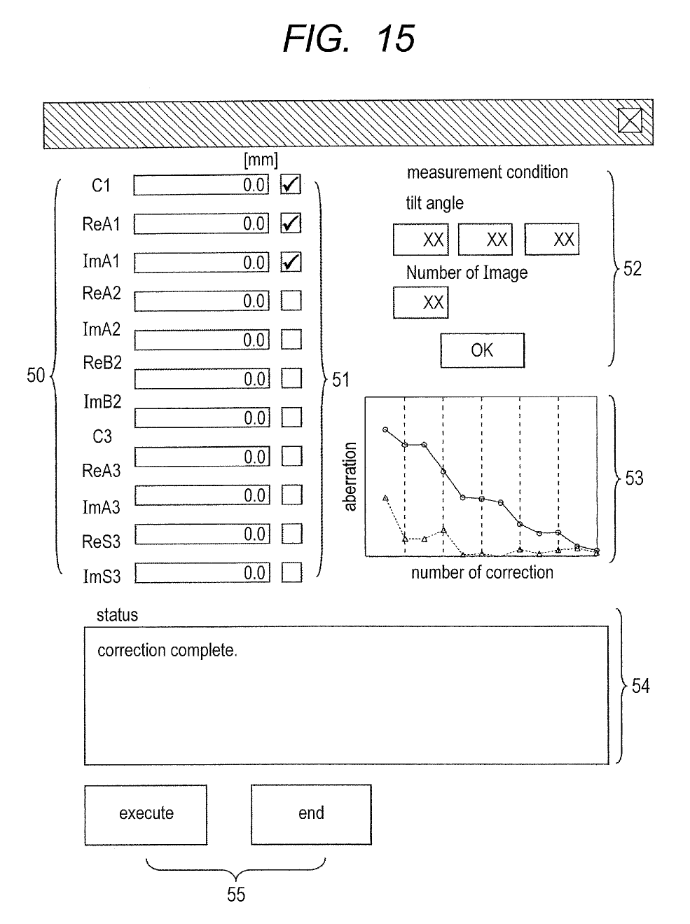

There is shown still another example as a further embodiment of the invention, where the present technique is applied to the case of executing an automatic operation using a measuring SEM. The measuring SEM is a device for measuring a distance between two points on data of an image measured by calculation of pixels. In FIG. 14, there is shown a system block diagram of the measuring SEM for use in the present embodiment. The measuring SEM according to the present embodiment is comprised of a load lock chamber 102 for introducing a sample into the device, a sample chamber provided with a sample stage 8 for holding a sample 9, a column 100 provided with a function for irradiating the sample 8 to detect a secondary electron, or a reflection electron, emitted therefrom, thereby outputting a detection result as a signal, a control PC 101 for processing the signal as outputted to thereby execute various operations, a variety of power supply controllers 20, 21, 22, and so forth. However, respective constituent elements are substantially similar in function•action to the contents of the description given in the first embodiment, omitting therefore description thereof.

The load lock chamber 102 is separated from the sample chamber of the main body of the device by a gate valve 31. The gate valve 31 is opened at the time when the sample is to be introduced into the device, whereupon the sample is introduced into the device by a sample transport mechanism 30. Further, adjustment of the device is carried out by use of a standard sample 32 placed on the sample stage 8.

The measuring SEM according to the present embodiment is provided with a boosting electrode 33 disposed above a magnetic-field type objective lens 7. An electrostatic lens is formed by application of an electric field to the boosting electrode, and fine adjustment of a focus can be effected by varying the intensity of the electrostatic lens. A voltage applied to the boosting electrode 33 is varied by controlling a boosting electrode power-supply control unit 34. Further, a voltage (retarding voltage) for forming a retarding field against an incident electron beam is applied to the sample stage 8 by a retarding power-supply control unit 35; however, the focus can also be adjusted by controlling the retarding voltage using the retarding power-supply control unit 35. Usually, response of the magnetic-field type objective lens to an excitation current is delayed due to aftereffects of magnetism, so that a focus can be speedily altered by adjustment of a boosting voltage, or the retarding voltage instead of the excitation current of the magnetic-field type objective lens.

To perform an automatic operation, a user checks a correction state through a GUI screen shown in FIG. 15, executing setting of a measurement condition, and a correction condition, as necessary, and checking of the results of the operation. Aberration coefficients as worked out are shown on a measured result display unit 50, and the user can designate a type of an aberration to be corrected on a correction setting unit 51. Processes for a correction start, and a correction completion, respectively, can be decided on a start and end button 55. The user can check a measurement condition from a correction condition setting display 52 to execute setting as necessary. Further, variation in aberration amount, due to a correction, is displayed on a correction progress display unit 53, so that the user can check the effect of the correction. Still further, the present state of the device, the correction state, and so forth are shown in characters on a message display unit 54, so that the user can perform a work, while checking such information as described.

### LIST OF REFERENCE SIGNS

1 . . . electron gun
2 . . . condenser lens
3 . . . deflection coil
4 . . . aberration corrector
5 . . . condenser lens
6 . . . scan coil
7 . . . objective lens
8 . . . sample stage
9 . . . sample
10 . . . detector
11 . . . image construction unit
12 . . . image display
13 . . . memory
14 . . . aberration coefficients calculation unit
15 . . . correction power setting unit
16 . . . amounts of displacement
17 . . . aberration coefficients
18 . . . input unit
19 . . . control unit
20 . . . deflection coil power-supply control unit
21 . . . aberration corrector power-supply control unit
22 . . . scan coil power-supply control unit
30 . . . sample transport mechanism
31 . . . gate valve
32 . . . standard sample
33 . . . boosting electrode
34 . . . boosting electrode power-supply control unit
35 . . . retarding power-supply control unit
40a, 40b . . . pattern
41 . . . pixel
42 . . . pixel
50 . . . measured result display unit
51 . . . correction setting unit
52 . . . correction condition setting display
53 . . . correction progress display unit
54 . . . message display unit
55 . . . start and end button
60, 61, 62, 63 . . . sample
70 . . . horizontal line
71 . . . vertical line
72 . . . grid pattern
73 . . . cross pattern
100 . . . SEM column
101 . . . control PC
102 . . . load lock chamber
110 . . . correction power information
111 . . . secondary electron brightness information

1. A charged particle beam device comprising:
an electron beam source for radiating an electron beam;
an electron optical system for irradiating a sample with the electron beam;
an electron beam detector for detecting an electron beam emitted from the sample irradiated with the electron beam;
an aberration corrector for removing an aberration component by application of an electric field, and an magnetic field, not rotationally symmetrical to each other; and
a deflector disposed on a side of the aberration corrector, adjacent to the electron beam source, for controlling a route of the electron beam passing through the electron optical system,
wherein a beam in an optical condition changed by use of the deflector is used for scanning on a sample having a predetermined pattern, thereby acquiring a plurality of images by use of beams differing in path from each other, and an image formed by cutting out one of the plural images in a scope containing the predetermined pattern, narrower than a region of one other image, is used as a reference image, a means for working out an amount of an aberration on the basis of a differential between the reference image and the one other image being provided.

2. The charged particle beam device according to claim 1, further comprising:
a means for acquiring a first image obtained by picking up an image of the sample having the predetermined pattern at a tilt angle of a first beam, and an azimuth thereof, and a second image obtained by picking up an image of the predetermined pattern under an optical condition where at least either of a tilt angle, and a azimuth differs from the tilt angle of the first beam, and the azimuth thereof;
a means for cutting out a region of the first image, so as to be smaller than a region of the second image, and to contain the predetermined pattern;
a means for using the first image cut out as the reference image, taking a differential between the reference image and the second image, and detecting a destination of the predetermined pattern in the second image on the basis of the differential, thereby working out an amount of movement, and
a means for working out the amount of an aberration on the basis of the amount of movement.

3. The charged particle beam device according to claim 2, wherein an aberration component is removed by feeding back the amount of an aberration to the aberration corrector.

4. The charged particle beam device according to claim 2, wherein an information piece on brightness distribution at respective azimuths is acquired on the basis of a secondary charged particle signal detected by the electron beam detector, and the aberration component is worked out from the information piece on the brightness distribution.

5. The charged particle beam device according to claim 2, wherein the first image is an image picked up by a beam in a non-tilted state.

6. The charged particle beam device according to claim 2, wherein an aberration corrected by the aberration corrector is an axial spherical aberration

7. The charged particle beam device according to claim 2, wherein the deflector is a 2-stage deflection coil.

8. The charged particle beam device according to claim 2, wherein the deflector is an electrostatic deflector.

9. A charged particle beam device comprising:
an electron optical system for irradiating a sample with an electron beam radiated from an electron beam source;
an electron beam detector for detecting an electron beam emitted from the sample irradiated with the electron beam;
an aberration corrector for removing an aberration component by application of an electric field, and an magnetic field, not rotationally symmetrical to each other; and
a deflector disposed on a side of the aberration corrector, adjacent to the electron beam source, for controlling a route of the electron beam passing through the electron optical system,
wherein there are further provided with a means for acquiring brightness distribution information on the basis of a secondary charged particle signal detected by the electron beam detector, a means for acquiring information pieces on a plurality of brightness distributions against the sample by changing an optical condition set by the deflector, and a means for working out an amount of a visual view offset between images of the sample, acquired under optical conditions differing from each other, from the information pieces on the plural brightness distributions.

10. The charged particle beam device according to claim 9, wherein the brightness distribution information is two-dimensional brightness distribution information.

11. The charged particle beam device according to claim 10, wherein the amount of the visual view offset is worked out by comparison of an image acquired under a first optical condition with an image acquired under a second optical condition, the respective images differing in visual field scope from each other.

12. The charged particle beam device according to claim 10, wherein the amount of the visual view offset is worked out by comparison of an image acquired under a first optical condition with an image acquired under a second optical condition, the respective images differing in resolution from each other.

13. The charged particle beam device according to claim 9, wherein the brightness distribution information is one-dimensional brightness distribution information.

14. The charged particle beam device according to claim 13, wherein the one-dimensional brightness distribution information is acquired by use of a sample where lines arranged at unequal intervals in the horizontal direction are disposed side by side with lines arranged at unequal intervals in the vertical direction.

15. The charged particle beam device according to claim 13, wherein the one-dimensional brightness distribution information is acquired by use of a sample having a grid pattern formed by combining lines arranged at unequal intervals in the horizontal direction with lines arranged at unequal intervals in the vertical direction.

16. The charged particle beam device according to claim 13, wherein the one-dimensional brightness distribution information is acquired by use of a sample having cross patterns arranged at unequal intervals.

17. The charged particle beam device according to claim 13, wherein the one-dimensional brightness distribution information is acquired by use of a sample having two lengths of lines orthogonally intersecting each other.
